(19) United States
(12) Patent Application Publication
(10) Pub. No.: US 2014/0099783 A1
(43) Pub. Date: Apr. 10, 2014

(54) METHOD OF ADDING AN ADDITIONAL MASK IN THE ION-IMPLANTATION PROCESS

(71) Applicant: Shangai Huali Microelectronics Corporation, Shanghai (CN)

(72) Inventors: ChaoRong LAI, Shanghai (CN); JianNing DENG, Shanghai (CN); HsuSheng CHANG, Shanghai (TW)

(73) Assignee: Shangai Huali Microelectronics Corporation, Shanghai (CN)

(21) Appl. No.: 14/043,107

(22) Filed: Oct. 1, 2013

(30) Foreign Application Priority Data
Oct. 8, 2012 (CN) 201210375752.7

(51) Int. Cl. H01L 21/266

(52) U.S. Cl. CPC H01L 21/266
USPC 438/514

(57) ABSTRACT

The present invention discloses a method of adding an additional mask in the ion-implantation process. It relates to technical field of ion implantation. This invention comprises: a mask plate is added upon the said MPW and the nitrogen element is implanted in the said MPW; the implanted nitrogen element is used for amorphizing the upper surface of the MPW. The advantageous effects of the above technical solution are as follows: the steps of the production process are simplified; the ion implantation mask will achieve 4 different doping concentrations of the ion implantation when the wafer is implanted. It means that it is possible to form 4 different gate oxide layers of different in thickness. However, it is essential to apply the photomask three times to achieve the same effect in the process of prior art. Consequently, the method of the present invention can reduce both the cost and the term of production process.

### CROSS-REFERENCE TO RELATED APPLICATIONS

The present application claims priority under the Paris Convention to Chinese application number CN 201210375752.7, filed on Oct. 8, 2012, the disclosure of which is herewith incorporated by reference in its entirety.

### TECHNICAL FIELD

The present invention relates to ion-implantation process, in particular relates to a method of adding an additional mask in the ion-implantation process.

### BACKGROUND OF THE INVENTION

Multi Project Wafer (MPW) services integrate a number of different integrated circuits designs onto the wafer while these integrated circuits have the same wafer fabrication process. After the wafer processing, every integrated circuit can get tens of sample dies. The amount of these sample dies can satisfy the requirement of planned experiments or tests during the design and development stages. The actual costs of the experimented wafer are shared by all members according to the area ratio of the dies, every one affords the part of his own. The actual cost is only 5%-10% of the standard cost. In this way, the cost of joining threshold is reduced during the development stages in such a manner that the sum of the costs imputed to each member. It also provides a comfortable environment for the integrated circuit designers and powerfully promotes the development of the integrated circuit industry.

Generally, it is essential to form different gate oxide layers due to the requirements of different processes in the design of the MPW. In the traditional process additional photomask is used to form some gate oxide layers of different thickness. Referring to the procedure in FIG. 1, it is supposed that the MPW consists of two kinds of gate oxide layers (Subject 1 and Subject 2). Firstly, a layer of gate oxide is formed as shown in FIG. 2. And then a photomask is put above Subject 1 area of the wafer in order to expose the photoresist to form a patterned gate oxide layer as shown in FIG. 3. Then the gate oxide of Subject 2 area is removed by ways of wet etching, which is shown in FIG. 4. And then a layer of gate oxide is deposited again as shown in FIG. 5. In this way, it forms a different gate oxide layers in Subject 1 area from the one in Subject 2 area. The differences between this traditional process used in

MPW and the traditional single project process used in single wafer are that a process of photomask is added in the MPW process, and a process of secondary depositing and wet etching is added as well. However, it increases the expense and the period time of the research and development about the process.

Chinese patent (CN 102800590A) has disclosed a method of forming the SiGe-HBT transistor based on SOT (Silicon-On-Insulator). By means of adding a photomask in the process of forming the SiGe-HBT transistor to make the ion implant area be limited in the designated area. In this way, it solves the problem that the resistance of the collecting electrodes shag) increases and the maximum cut-off frequency (Ft) significantly decreases in the SiGeHBT device based on SOT whose thickness is no more than 150 nm.

In the above patent, it only uses the photomask to conduct the ion implantation in designated area, but it is not available to use the photomask to control the thickness of the ion implant layer. In actual use, it can only control the position of the ion implantation area but not its thickness. Consequently, the method in the above patent has some limitation in the actual processes.

Chinese patent (CN 102694027A) has disclosed a structure of the junction at non-equilibrium of the super junction device. In this patent publication several P columns are set up with different doping concentrations, and then according to the distribution of the transverse electric in everywhere the ion-implant areas of the P column in the layout are adjusted in order to make the P column completely be exhausted when it reaches the breakdown voltage. All the P columns are implanted under the mask at the same time, thus the amount of the implanted ion in the terminal of the junction is controlled, after many times of ion implanting and epitaxy process, several P columns with different doping concentrations are formed.

The above patent uses the mask in the ion implant process to control the amount of the ion implantation, and then the P columns with different doping concentration are formed. In the above patent, it is difficult to control the thickness of the ion implant layer. Consequently, the method in the above patent has some limitation in the actual process.

### SUMMARY OF THE INVENTION

Due to the defects of the traditional art, the present invention discloses a method of adding an additional mask in the ion-implantation process, comprising:

A method of adding an additional mask in the ion-implantation process which is applied to the MPW, wherein a mask is added upon the said MPW, and the nitrogen element is implanted in the said MPW; the said nitrogen element is used for amorphizing the upper surface of the MP W.

According to the above method, wherein the nitrogen element is implanted in the said MPW by an ion implantation machine.

According to the above method, wherein 4 different doping concentrations of nitrogen element are implanted into the said MPW.

According to the above method, wherein the different doping concentrations of the nitrogen element are implanted in different areas of the said same MPW.

According to the above method, wherein the said method comprises the following steps:
Step a, an ion implantation machine is applied to implant the nitrogen element in the said MPW by with the existence of the said additional mask plate;
Step b, gate oxide layers are grown upon the surface of the said MPW;
Step c, the gate oxide layers of different thickness are formed according to the different dosages of the implanted nitrogen element.

The advantageous effects of the above technical solution are as follows:
The steps of the production process are greatly simplified. Meanwhile, the ion implantation mask will achieve 4 different doping concentrations of the ion implantation when the wafer is implanted. It means that it is possible to form 4 different gate oxide layers of different thickness, while it is essential to apply the photomask three times to achieve the same effect in the process of the prior art. Consequently, the method of the present invention can reduce both the cost and the term of production process.

### BRIEF DESCRIPTIONS OF THE DRAWINGS

FIG. 1 is a flow diagram of depositing gate oxide layers on MPW in the prior art;

FIG. 2 is a structure diagram of depositing a gate oxide layer on the upper surface of an wafer in the prior art;

FIG. 3 is a structure diagram of depositing a layer of photoresist on the upper surface of the wafer for the first time in the prior art;

FIG. 4 is a structure diagram of removing the gate oxide layer of Subject 2 area of the wafer in the prior art;

FIG. 5 is a structure diagram of depositing a layer of photoresist on the upper surface of the wafer for the second time in the prior art;

FIG. 6 is a flow diagram of an embodiment of the present invention.

FIG. 7 is a structure diagram of an embodiment of ion-implanting with the mask of the ion implantation machine of the present invention.

FIG. 8 is a structure diagram of an embodiment of depositing gate oxide layers after the ion implantation process in the present invention.

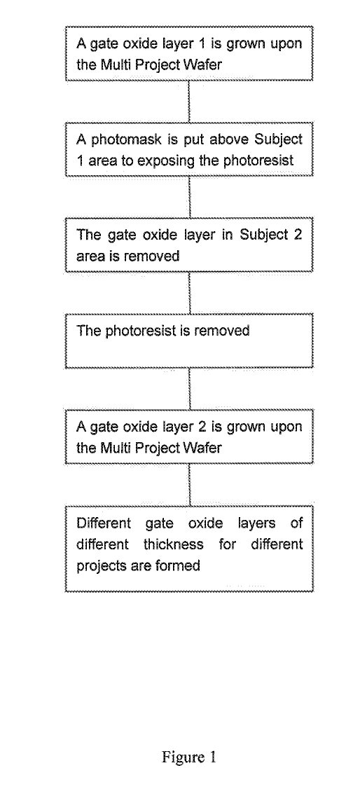

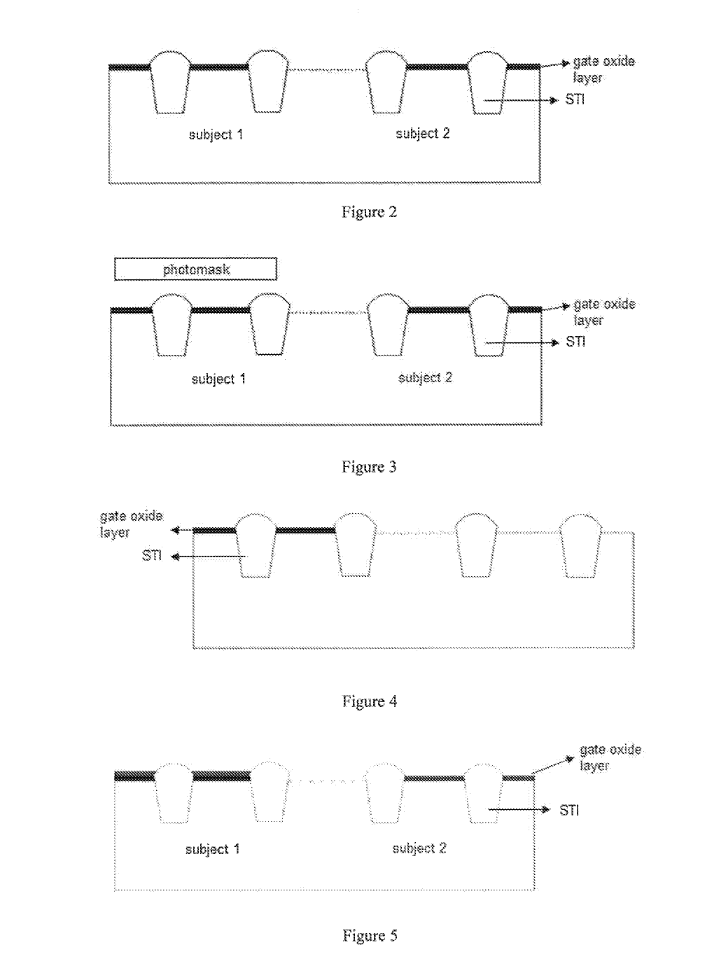

### DESCRIPTIONS OF THE PREFERRED EMBODIMENT(S)

The present invention will be further illustrated in combination with the following figures and embodiments, but it should not be deemed as limitation of the present invention.

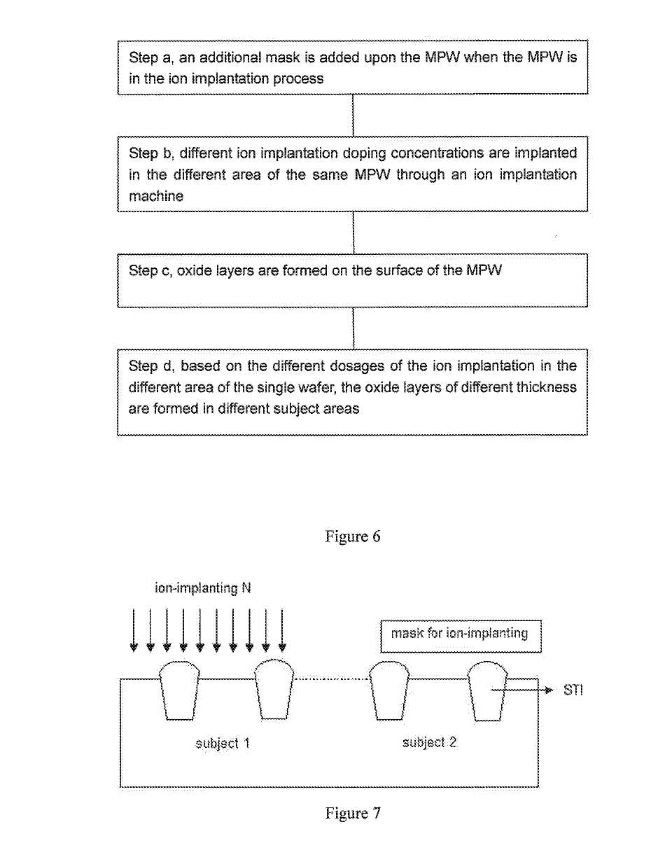

FIG. 6 is a schematic view of the process flow diagram for an embodiment in the MPW of the present invention, wherein it includes the following steps:
Step a, an additional mask is added upon the MPW when the MPW is in the ion implantation process;
Step b, as shown in FIG. 7, nitrogen ion is implanted into the MPW through an ion implantation machine, furthermore, different ion implantation doping concentrations are implanted in the different area of the same MPW; for example, there will be at most four different doped regions with different doping concentration conditions in single wafer;
Step c, oxide layers are formed on the surface of the MPW, for example, the oxide layer may be a gate insulation layer and the like;
Step d, based on the different dosages of the ion implantation in the different area of the single wafer, the oxide layers of different thickness are formed in different subject areas, in other words, each doped region having a different doping concentration will be covered by a oxide layer with a different thickness from the other oxide layers covered on the other doped regions.

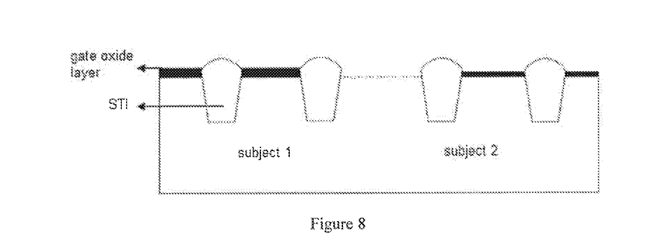

At last, the oxide layers which may be gate oxide layer are formed as showed in FIG. 8.

In the manufacturing process of the semiconductor device, the purpose of using elements of group 3 or group 5 of periodic table as the dopant is to change the electrical characteristics of silicon, but the ion is not limited to the group 3 or group 5, some particular ion also can change the electrical characteristics of silicon. When the nitrogen element is implanted into the wafer, the amorphization occurs on the surface of the silicon substrate. Consequently, it is easy to form the oxide layer on the surface of the wafer through an amorphizing process. The nitrogen element remained in the wafer will be dislodged from the wafer as N₂ gas when the wafer is heated, thus the amorphizing process will not change the quality of the gate oxide layer. Therefore, with the usage of the mask of the ion implantation machine in the ion implantation, the different areas of the wafer will be doped with nitrogen element and different doping concentrations are applied in the different areas. The more the dosage value is, the thicker the gate oxide layer will be. As at most 4 different dosages of nitrogen element are implanted in different areas of this wafer, it can at most form 4 kinds of gate oxide layers of different in thickness.

The dosages of the nitrogen element can be calculated from the dummy wafer which could be put into experiment, and then the results of the experiments can be used directly in the MPW.

Although a typical embodiment of a particular structure of the specific implementation way has been given with the above description and the figures, it is appreciated that other changes based on the spirit of this invention may also be made. Though the preferred embodiments are proposed above, these contents will never be the limitation of this invention.

It is obvious for the skilled in the art to make varieties of changes and modifications after reading the above descriptions. Hence, the Claims attached should be regarded as all the changes and modifications which cover the real intention and the range of this invention. Any and all equivalent contents and ranges in the range of the Claims should be regarded belonging to the intention and the range of this invention.

1. A method of adding an additional mask in the ion-implantation process, which is applied to the MPW, wherein a mask is added upon the said MPW and the nitrogen element is implanted in the said MPW; the implanted nitrogen element is used for amorphizing the upper surface of the MPW.

2. The method according to claim 1, wherein the nitrogen element is implanted in the said MPW by an ion implantation machine.

3. The method according to claim 1, wherein 4 different doping concentrations of nitrogen element are implanted into the said MPW.

4. The method according to claim 3, wherein the different doping concentrations of the nitrogen element are implanted in different areas of the same MPW

5. The method according to claim 1, wherein the said method comprises the following steps:
Step a, an ion implantation machine is applied to implant the nitrogen element into the said MPW with the said additional mask plate;
Step b, gate oxide layers are grown upon the surface of the said MPW;
Step c, the gate oxide layers of different thickness are formed according to the different dosages of the implanted nitrogen element.

6. The method according to claim 2, wherein the said method comprises the following steps:
Step a, an ion implantation machine is applied to implant the nitrogen element into the said MPW with the said additional mask plate;
Step b, gate oxide layers are grown upon the surface of the said MPW;
Step c, the gate oxide layers of different thickness are formed according to the different dosages of the implanted nitrogen element.

7. The method according to claim 3, wherein the said method comprises the following steps:
Step a, an ion implantation machine is applied to implant the nitrogen element into the said MPW with the said additional mask plate;
Step b, gate oxide layers are grown upon the surface of the said MPW;
Step c, the gate oxide layers of different thickness are formed according to the different dosages of the implanted nitrogen element.

8. The method according to claim 4, wherein the said method comprises the following steps:
Step a, an ion implantation machine is applied to implant the nitrogen element into the said MPW with the said additional mask plate;
Step b, gate oxide layers are grown upon the surface of the said MPW;
Step c, the gate oxide layers of different thickness are formed according to the different dosages of the implanted nitrogen element.
